(19) United States
(12) Patent Application Publication
(10) Pub. No.: US 2026/0176759 A1
(43) Pub. Date: Jun. 25, 2026

(54) METHOD OF DEPOSITING LOW DIELECTRIC CONSTANT MATERIAL

(71) Applicant: ASM IP Holding B.V., Almere (NL)

(72) Inventors: Hirotsugu Sugiura, Tokyo (JP); Yoshiyuki Kikuchi, Tokyo (JP); Ippei Yanagisawa, Sagamihara-shi (JP); Keigo Kurumisawa, Tokyo (JP); Takashi Nagasawa, Tokyo (JP)

(21) Appl. No.: 19/422,675

(22) Filed: Dec. 17, 2025

Related U.S. Application Data
(60) Provisional application No. 63/737,138, filed on Dec. 20, 2024.

(51) Int. Cl. C23C 16/455; C23C 16/34; C23C 16/40; H01J 37/32

(52) U.S. Cl. CPC C23C 16/45542; C23C 16/345; C23C 16/401; C23C 16/45553; H01J 37/32146; H01J 37/32449; H01J 2237/3321

(57) ABSTRACT

Methods and systems for forming a structure including a low dielectric constant material layer on a surface of a substrate and structures and devices formed using the methods or systems are disclosed. Exemplary methods include providing a substrate within a reaction chamber of a reactor system, providing one or more precursors to the reaction chamber, providing one or more reactants including a mixture of a nitrogen- and oxygen-containing reactants and a hydrogen-containing reactant, and providing pulsed plasma power to polymerize the one or more precursors within the reaction chamber.

### CROSS-REFERENCE TO RELATED APPLICATIONS

This application claims priority to U.S. Provisional Patent Application Ser. No. 63/737,138 filed Dec. 20, 2024 and titled METHOD OF DEPOSITING LOW DIELECTRIC CONSTANT MATERIAL, the disclosure of which is hereby incorporated by reference in its entirety.

### FIELD OF DISCLOSURE

The present disclosure generally relates to methods of depositing layers and to forming structures suitable for use in the manufacture of electronic devices. More particularly, examples of the disclosure relate to methods of forming structures that include dielectric layers, to structures and devices including such layers, and to systems for performing the methods and/or forming the structures and/or devices.

### BACKGROUND OF THE DISCLOSURE

During the manufacture of devices, such as semiconductor devices, it is often desirable to fill features (e.g., trenches or gaps) on the surface of a substrate with dielectric material. In some cases, it may be desirable to fill the features with a low dielectric constant (low-k) material, such as carbon material (e.g., silicon oxygen carbide material), or other dielectric material, such as silicon oxide (SiOₓ), silicon nitride (SiNₓ), or the like. By way of examples, dielectric material can be used as an intermetal dielectric layer on patterned metal features, a gap fill for fully aligned vias in back-end-of-line processes, an inner isolation layer for gate all around devices, insulating layers in resistive random-access memory (ReRAM) devices, and the like.

Some dielectric material deposition processes can use organic silanes or oxysilanes and an oxidant to form an initially flowable material. The material can be deposited using thermal energy or a remote plasma to activate the oxidant. Such techniques often include relatively long curing or annealing steps to increase a density of the deposited material and to reduce a dielectric constant of the material.

Although these techniques can work well for some applications, filling features using traditional deposition techniques has several shortcomings, particularly as the size of the features to be filled decreases. For example, a dielectric constant of the cured or annealed material can vary significantly (e.g., shift upward) using conventional techniques, leading to undesired variation in device performance. In addition, dielectric material formed using typical techniques can be prone to blistering. Additionally, the deposition steps and/or post deposition steps (e.g., annealing or curing) can be relatively long.

Accordingly, improved methods for forming low dielectric constant material on a surface of a substrate, particularly for methods of filling gaps on a substrate surface with such material, which mitigate variation of the dielectric constant of the material and/or that provide desired material properties (e.g., less or no blistering) and/or that can be performed relatively quickly, are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

Various embodiments of the present disclosure relate to methods of forming structures suitable for use in the formation of electronic devices. While the ways in which various embodiments of the present disclosure address drawbacks of prior methods and structures are discussed in more detail below, in general, exemplary embodiments of the disclosure provide improved methods for forming structures that include low dielectric constant material, structures including the low dielectric constant material, and systems for performing the methods and/or forming the structures. The methods described herein can be used to fill features on a surface of a substrate. In accordance with examples of the disclosure, the low dielectric constant material exhibits relatively little blistering and/or shift in dielectric constant over time.

In accordance with various embodiments of the disclosure, a method of depositing a low dielectric constant material on a surface of a substrate is provided. Examples of the method include providing a substrate, comprising a gap feature on a surface thereon, within a reaction chamber, providing one or more precursors to a reaction space within the reaction chamber, providing a reactant to the reaction space, and providing a pulsed plasma power to at least one electrode to form a plasma within the reaction space to thereby form the low dielectric constant material. In accordance with aspects of these examples, the reactant comprises a mixture of (e.g., 4 volumetric % or more of) a nitrogen- and oxygen-containing reactant and (e.g., the remainder of) a hydrogen-containing reactant. For example, the reactant can consist essentially of or consist of the nitrogen- and oxygen-containing reactant and a hydrogen-containing reactant, alone or with an inert gas. In some cases, the hydrogen-containing reactant includes nitrogen. For example, the hydrogen-containing reactant can be or include one or more of NH₃ or CₓH_{y}NH₂, where x is between 1 and 3 and y is between 3 and 7. The nitrogen- and oxygen-containing reactant can be or include NₓO_{y}, where x is between 1 and 2 and y is between 1 and 4. In accordance with examples of the disclosure, the reactant does not include O₂, O₃, H₂O, and/or H₂O₂. In accordance with various aspects of these examples, the one or more precursors include an alkoxy silane precursor. The alkoxy silane precursor can be represented by the formula SiOₓC_{y}H_{z}, where x is between 1 and 4, y is between 3 and 10, and z is between 9 and 24. In some cases, at least one of the one or more precursors includes a ring structure including a chemical formula represented by —(Si(R₁,R₂)—O)ₙ—, where n ranges from about 3 to about 10, and wherein R₁ and R₂ are independently selected from H, CH₃, C₂H₅, C₂H₃, CH(CH₃)₂, CH₂CH(CH₃)₂, OCH₃, OC₂H₅, C₃H₆—NH₂. In some cases, at least one of the one or more precursors comprises a linear structure comprising a chemical formula represented by R₃—(Si(R₁,R₂)ₘ—O₍ₘ₋₁₎)—R₄, where m can range from about 1 to about 7, and wherein R₁, R₂, R₃ and R₄ are independently selected from H, CH₃, C₂H₅, C₂H₃, CH(CH₃)₂, CH₂CH(CH₃)₂, OCH₃, OC₂H₅, C₃H₆—NH₂. In accordance with further aspects, a duty cycle of power applied to the at least one electrode during the step of providing pulsed plasma power to the at least one electrode is between 1% and 50%. In accordance with further examples, the method includes a step of curing the low dielectric constant material to form cured low dielectric constant material. In such cases, the method can further include a step of treating the cured low dielectric constant material to form treated low dielectric constant material.

In accordance with yet further exemplary embodiments of the disclosure, a structure is formed, at least in part, according to a method described herein. The structure can include a low dielectric constant material. The low dielectric constant material can be deposited over features having an aspect ratio of 1:1 or more. In accordance with examples of the disclosure, a dielectric constant of the low dielectric constant material varies by less than two percent over three or more days in an ambient environment. In some cases, a dielectric constant of the low dielectric constant material decreases in an ambient environment. In accordance with yet further examples, a leakage current of the low dielectric constant material decreases in an ambient environment.

In accordance with further examples of the disclosure, a device can be formed using a method and/or include a structure as described herein. The device can be or include, for example, a FinFET, a gate all around nanowire FET, a cross-point cell, a memory device, or a logic device.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates normalized dielectric constant values over time for various process conditions, including those in accordance with the present disclosure.

FIG. 3 illustrates optical emission spectra at UV region from deposition plasma, measured by optical spectrometer, for various process conditions, including those in accordance with the present disclosure.

FIGS. 4A and 4B illustrate FTIR absorbance spectra normalized by thickness of film (unit: nm) for material deposited in accordance with exemplary embodiments of the disclosure.

FIG. 5 illustrates gapfill performance of various process conditions, including those in accordance with exemplary embodiments of the disclosure.

FIG. 6 illustrates examples of reduction in blistering of a low dielectric constant material during a post-deposition treatment in accordance with examples of the disclosure.

FIG. 7 illustrates substrates after a 2-step treatment in accordance with examples of the disclosure.

FIG. 8 illustrates OH generation in plasma with a combination of N₂O and NH₃, as measured by OES.

FIG. 9 illustrates a pulsed plasma step in accordance with examples of the disclosure.

FIG. 10 illustrates a structure in accordance with further examples of the disclosure.

FIG. 11 illustrates a reactor system in accordance with embodiments of the disclosure.

FIG. 12 illustrates a FinFET structure including a dielectric material layer in accordance with exemplary embodiments of the disclosure.

FIG. 13 illustrates a gate all around device structure including a dielectric material layer in accordance with further exemplary embodiments of the disclosure.

FIG. 14 illustrates a cross-point device structure including a dielectric material layer in accordance with exemplary embodiments of the disclosure.

FIG. 15 illustrates a device structure including a back-end-of-line intermetal dielectric gapfill layer in accordance with exemplary embodiments of the disclosure.

FIG. 16 illustrates a device structure including a back-end-of-line fully aligned via structure and a gapfill layer in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of depositing a low dielectric constant material on a surface of a substrate, to methods of forming structures and devices, to structures and devices formed using the methods, and to systems for performing the methods and/or forming the structures and devices. By way of examples, the methods described herein can be used to fill features, such as gaps (e.g., trenches or vias), on a surface of a substrate with the low dielectric constant material. The terms gap and recess can be used interchangeably herein.

To mitigate void and/or seam formation during a gap-filling process, deposited material can be initially flowable and flow within the gap to fill the gap. Exemplary structures described herein can be used in a variety of applications and devices, including, but not limited to, cell isolation in 3D cross-point memory devices, self-aligned vias, dummy gates, reverse tone patterns, PC RAM isolation, cut hard masks, DRAM storage node contact (SNC) isolation, as an intermetallic gap-fill layer on or between patterned metal features (which can include, for example, one or more of Ru, Co, Cu, Ta, TaN, Ti, TiN, W), a gap fill for fully aligned vias in back-end-of-line (BEOL) processes, a dielectric on dielectric in BEOL processes—e.g., for memory or logic devices, inner isolation for gate all around devices, insulating layers in resistive random-access memory (ReRAM) devices, a shallow trench isolation layer of a FinFET device, and the like.

As set forth in more detail below, exemplary methods can be used to form structures that include a low dielectric constant material. In accordance with examples of the disclosure, a dielectric constant of the deposited low dielectric constant material exhibits relatively low shift (i.e., the dielectric constant does not change much over time). Additionally or alternatively, methods described herein can be used to deposit a low dielectric constant material that exhibits relatively little blistering during a post-treatment process.

In this disclosure, gas can refer to material that is a gas at normal temperature and pressure, a vaporized solid and/or a vaporized liquid, and may be constituted by a single gas or a mixture of gases, depending on the context. A gas other than a process gas, i.e., a gas introduced without passing through a gas distribution assembly, such as a showerhead, other gas distribution device, or the like, may be used for, e.g., sealing a reaction space, which includes a seal gas, such as a rare gas. In some cases, such as in the context of deposition of material, the term precursor can refer to a compound that participates in the chemical reaction that produces another compound, and particularly to a compound that constitutes a film matrix or a main skeleton of a film, whereas the term reactant can refer to a compound, in some cases, other than a precursor, that activates a precursor, modifies a precursor, or catalyzes a reaction of a precursor; a reactant may provide an element (such as O, H, N, C) to a film matrix and become a part of the film matrix when, for example, power (e.g., radio frequency (RF) power) is applied. In some cases, the terms precursor and reactant can be used interchangeably. In some cases, a reactant can include a plurality of compounds. The term inert gas refers to a gas that does not take part in a chemical reaction to an appreciable extent and/or a gas that excites a precursor (e.g., to facilitate polymerization of the precursor) when, for example, power (e.g., RF power) is applied, but unlike a reactant, it may not become a part of a film matrix to an appreciable extent. Exemplary inert gases include argon, helium, nitrogen, and any mixture thereof.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group Ill-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within at least a portion of a layer or bulk material of the substrate. By way of examples, one or more features can have a width of about 10 nm to about 100 nm, a depth or height of about 30 nm to about 1,000 nm, and/or an aspect ratio of about 1, 3, 10, 100, or more.

In some embodiments, film refers to a layer extending in a direction perpendicular to a thickness direction. In some embodiments, layer refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term low dielectric constant material or low-k material layer or low-k material can refer to material whose dielectric constant is less than the dielectric constant of silicon dioxide or less than 3.8 or between about 2.5 and about 3.

As used herein, the term structure can refer to a partially or completely fabricated device structure. By way of examples, a structure can be a substrate or include a substrate with one or more layers and/or features formed thereon.

As used herein, the term cyclic deposition process can refer to a vapor deposition process in which deposition cycles, typically a plurality of consecutive deposition cycles, are conducted in a process chamber. Cyclic deposition processes can include cyclic chemical vapor deposition (CVD) and atomic layer deposition (ALD) processes. A cyclic deposition process can include one or more cycles that include plasma activation of a precursor, a reactant, and/or an inert gas.

In this disclosure, continuously can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

A flowability (e.g., an initial flowability) can be determined as follows:

TABLE 1

| bottom/top ratio (B/T) | Flowability |
|---|---|
| 0 < B/T < 1 | None |
| 1 ≤ B/T < 1.5 | Poor |
| 1.5 ≤ B/T < 2.5 | Good |
| 2.5 ≤ B/T < 3.5 | Very good |
| 3.5 ≤ B/T | Extremely good |

where B/T refers to a ratio of thickness of film deposited at a bottom of a recess to thickness of film deposited at a top surface where the recess is formed, before the recess is filled. Typically, the flowability is evaluated using a wide recess having an aspect ratio of about 1:1 or less, since generally, the higher the aspect ratio of the recess, the higher the B/T ratio becomes. The B/T ratio generally becomes higher when the aspect ratio of the recess is higher. As used herein, a flowable film or material exhibits good or better flowability.

As set forth in more detail below, flowability of material can be temporarily obtained when one or more precursors are polymerized by, for example, excited species formed using a plasma. The resultant polymer material can exhibit temporarily flowable behavior. When a deposition step is complete and/or after a short period of time (e.g., about 3.0 seconds), the film may no longer be flowable, but rather becomes solidified, and thus, a separate solidification process may not be employed. In some cases, a curing step can be used.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, etc. in some embodiments. Further, in this disclosure, the terms including, constituted by, and having, and the like can refer independently to typically or broadly comprising, comprising, consisting essentially of, or consisting of in some embodiments. In this disclosure, any defined meanings do not necessarily exclude ordinary and customary meanings in some embodiments.

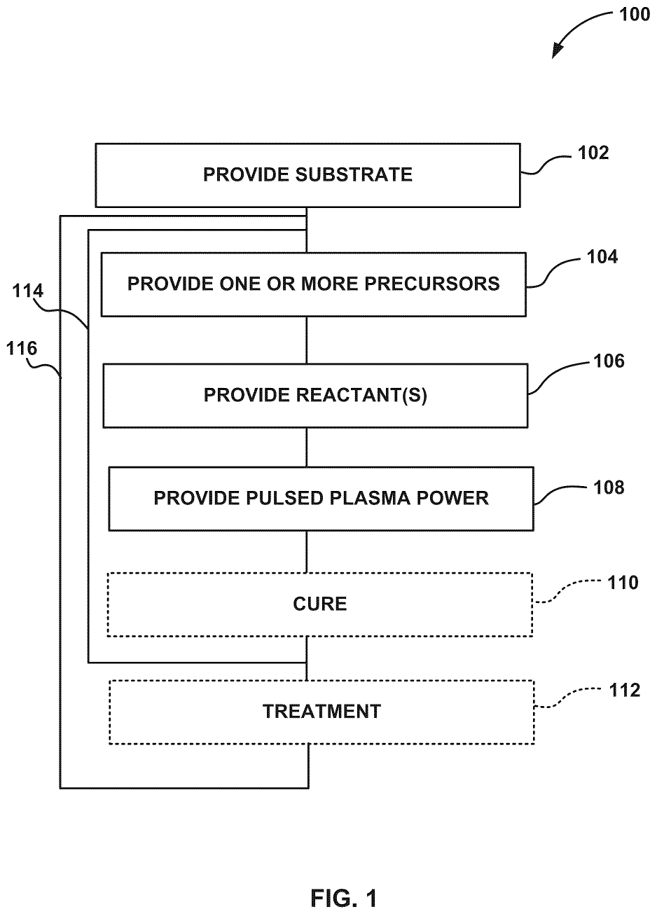

Turning now to the figures, FIG. 1 illustrates a method 100 of depositing a low dielectric constant material on a surface of a substrate in accordance with exemplary embodiments of the disclosure. Method 100 includes the step of providing a substrate within a reaction chamber (step 102), providing one or more precursors to the reaction chamber (step 104), providing a reactant (step 106), and providing pulsed plasma power to polymerize the one or more precursors within the reaction chamber (step 108). Method 100 can also include a treatment step (step 110) and/or a curing step (step 112). As illustrated, method 100 can include repeating steps 104-110 a number of times prior to step 112 (loop 112) and/or repeating steps 104-112 a number of times (loop 116).

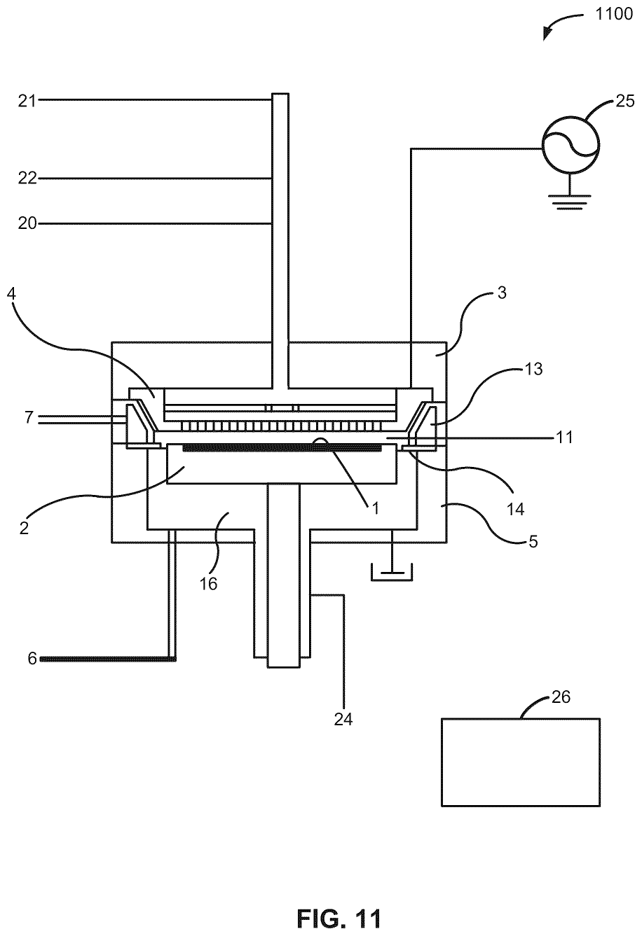

During step 102, a substrate is provided into a reaction chamber of a gas-phase reactor. In accordance with examples of the disclosure, the reaction chamber can form part of a chemical vapor deposition reactor, such as a plasma-enhanced chemical vapor deposition (PECVD) reactor or plasma-enhanced atomic layer deposition (PEALD) reactor. Various steps of methods described herein can be performed within a single reaction chamber or can be performed in multiple reaction chambers, such as reaction chambers of a cluster tool. An exemplary reactor is described in more detail below in connection with FIG. 11.

During step 102, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be less than or equal to 450° C. or less than or equal to 300° C. or less than or equal to 200° C.

As noted above, with typical low dielectric constant material deposition techniques, particularly those conducted at less than or equal to 200° C., a dielectric constant of the low dielectric constant material can shift or vary over time. This leads to degradation in device performance. Deposition techniques described herein mitigate or obviate these issues.

During providing one or more precursors to the reaction chamber step 104, one or more precursors for forming the low dielectric constant material layer are provided to a reaction space within the reaction chamber. Exemplary precursors can include a compound comprising carbon and/or silicon. In accordance with examples of the disclosure, the one or more precursors comprise a compound comprising a cyclic structure. The cyclic structure can include silicon—e.g., silicon and oxygen. The one or more precursors can include a compound that includes Si—O bonds. The one or more precursors can include a compound that includes an organosilicon compound, such as a cyclic organosilicon compound. The one or more precursors can include a compound that includes a siloxane and/or an alkoxy silane. Exemplary alkoxy silane precursors can be represented by the formula SiOₓC_{y}H_{z}, where z is between 1 and 4, y is between 3 and 10, and z is between 9 and 24.

Particular exemplary precursors include one or more of octamethylcyclotetrasiloxane (OMCTS), tetramethylcyclotetrasiloxane (TMCTS), octamethoxydodecasiloxane (OMODDS), octamethoxycyclotetrasiloxane (OMOCTS), dimethyldimethoxysilane (DM-DMOS), diethoxymethlsilane (DEMS), dimethoxymethylsilane (DMOMS), vinylmethyldimethoxysilane (VMDMOS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), and dicyclopentyldimethoxysilane (DcPDMS).

In accordance with further examples of the disclosure, the one or more precursors comprise an amino-alkyl siloxane precursor, such as 1,3-bis(3aminopropyl)tetramethyldisiloxane. In accordance with additional examples of the disclosure, the at least one of the one or more precursors comprises a ring structure comprising a chemical formula represented by —(Si(R₁,R₂)—O)ₙ—, where n ranges from about 3 to about 10 or about 3 to about 6, and wherein R₁ and R₂ are independently selected from H, CH₃, C₂H₅, C₂H₃, CH(CH₃)₂, CH₂CH(CH₃)₂, OCH₃, OC₂H₅, C₃H₆—NH₂.

By way of particular examples, wherein n can be 4 and R₁=R₂=CH₃; or n can be 4, R₁=H, and R₂=CH₃. In accordance with further examples, at least one of the one or more precursors comprises a linear structure comprising a chemical formula represented by R₃—(Si(R₁,R₂)ₘ—O₍ₘ₋₁₎)—R₄, where m can range from about 1 to about 7 to or from about 1 to about 4, and wherein R₁, R₂, R₃ and R₄ are independently selected from H, CH₃, C₂H₅, C₂H₃, CH(CH₃)₂, CH₂CH(CH₃)₂, OCH₃, OC₂H₅, C₃H₆—NH₂. By way of particular examples, m can be 1, R₁=R₂=CH₃, and R₃=R₄=OCH₃; m can be 2, R₁=R₂=CH₃, and R₃=R₄=OCH₃; or m can be 2, R₁=C₃H₆—NH₂, R₂=CH₃, and R₃=R₄=CH₃.

A flowrate of the one or more precursors to the reaction chamber can vary according to other process conditions. By way of examples, the flowrate can be from about 100 sccm to about 3,000 sccm. Similarly, a duration of each step of providing a precursor to the reaction chamber can vary, depending on various considerations.

During step 106, one or more reactants are provided to the reaction chamber. The one or more reactants can be flowed to the reaction space of the reaction chamber at the same time or overlapping in time with the step of providing one or more precursors to the reaction chamber. In this case, a CVD reaction can occur. In some cases, the reactant and or the one or more precursors can be pulsed to the reaction chamber for a cyclical process, such as a cyclical CVD or ALD process.

Exemplary reactants provided during step 106 include a mixture of 4 volumetric % or more of a nitrogen- and oxygen-containing reactant and a hydrogen-containing reactant. The nitrogen- and oxygen-containing reactant can be or include NₓO_{y}, where x is between 1 and 2 and y is between 1 and 4. The hydrogen-containing reactant include nitrogen and/or carbon in addition to hydrogen. In some cases, the hydrogen-containing reactant includes one or more of NH₃ and CₓH_{y}NH₂, where x is between 1 and 3 and y is between 3 and 7. In some cases, the hydrogen-containing reactant includes one or more of NH₃, a mixture of nitrogen and hydrogen, and amino family reactants, such as hydrazine, monomethylamine, dimethylamine, trimethylamine, monoethylamine, and diethylamine, in any combination. In accordance with examples of the disclosure, the reactant does not include O₂, O₃, H₂O, and/or H₂O₂ (e.g., in greater than trace amounts—e.g., less than 1 or 0.5 or 0.1 volumetric percent).

Use of certain oxidants, such as O₂, O₃, H₂O, and/or H₂O₂ has a potential to generate OH or H₂O in the plasma, which can undesirably increase a dielectric constant of the low dielectric constant material. Also, some of the combinations between alkoxy silane precursors and oxidants and/or reactants can create hydrophilic functional group in the film, like CO or OH, which cause degradation (e.g., increase) of the dielectric constant of the low dielectric constant material over time by absorbing moisture.

In accordance with examples of the disclosure, use of the nitrogen- and oxygen-containing reactant, particularly with alkoxy silane precursors, produced low dielectric constant material with relatively low dielectric constant shift over time. Further, use of the nitrogen- and oxygen-containing reactant allows for increased precursor variety, while maintaining desired properties of the low dielectric constant material.

In some cases, an inert gas can be provided to the reaction space during method 100. Exemplary inert gases include helium or argon or a mixture thereof.

During step 108 of providing pulsed plasma power, pulsed plasma power is provided to at least one electrode to form a plasma within the reaction space to thereby form the low dielectric constant material. For example, during step 108, one or more precursors or derivatives thereof are polymerized into the initially viscous material using excited species. The initially viscous carbon material can become solid material—e.g., through further reaction with excited species and/or during curing step 110.

The plasma formed during step 108 can be generated using a direct plasma system, such as the direct plasma system described in more detail below in connection with reactor system 1100, and/or using a remote plasma system. A power used to generate the plasma during step 106 can be between 10 W and 2,000 W or be between about 300 W and about 500 W. A frequency of the power can range from 1,000 kHz to 200 MHz with single or dual (e.g., RF) power sources. In some cases, a frequency of power for the step of providing pulsed plasma power comprises a high RF frequency (e.g., over 1 MHz or about 13.56 MHz) and a low RF frequency (e.g., less than 500 kHz or about 430 kHz). The lower frequency power can be applied to either an anode or a cathode of a plasma generation system. A pulse on time of the low RF frequency power can be about 1 kHz to about 100 kHz and duty cycle can be about 10% to about 100% or less than 50% or between 1% and 50%.

A pressure within the reaction space during the step of providing pulsed plasma power to at least one electrode can be between 10 and 10,000 Pa. A temperature during step 108 can be less than 200° C.

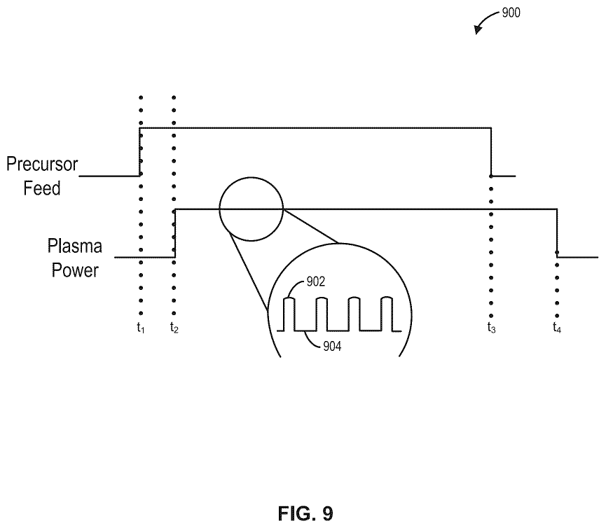

FIG. 9 illustrates a pulsed plasma step 900 in accordance with examples of the disclosure. As illustrated in FIG. 1 and FIG. 9, step 104 of providing one or more precursors can begin at a time t1. Optionally, one or more reactants can be provided to the reaction chamber at t1 or prior to t2. Thereafter, at t2, plasma power is provided to polymerize the one or more precursors. At t3, a flow of the one or more precursors and/or reactant(s) is ceased, and at t4, the power to form the plasma is reduced to extinguish the plasma. The illustrated example can be a pulsed plasma-enhanced chemical vapor deposition method.

During the period between t2 and t4, the plasma power can be pulsed, as illustrated in the enlarged portion of FIG. 9. A pulse can include a pulse on time 902 and a pulse off time 904, which can be repeated during t2-t4. Pulse on time 902 for the pulsed plasma power can be less than 50 μseconds, or about 10 μseconds to about 20 μseconds. Pulse off time 904 can be longer than pulse on time 902—e.g., greater than 2 or 5 times the pulse on time, or about 7 to about 10 times the pulse on time. Or, the RF on duty cycle can be less than 50% (e.g., between 1% and 50%). The RF on time and RF off time is thought to enable control of the flowable deposition process by affecting the sticking coefficient of the polymerized precursor(s). If a long RF on time is applied, an amount of precursor(s) excitation may be too much in gas phase, resulting in large particles, such as flakes, forming in the gas phase. Also, shorter RF off times can result in particle and void formation due to lack of enough surface migration. By controlling chemical reactions and sticking coefficiency of precursors at the substrate surface using a pulsed plasma, both good gap-filling capability and high film qualities of deposited dielectric material layer are achieved.

Returning again to FIG. 1, method 100 can include curing step 110. During step 110, the low dielectric constant material is used to form cured low dielectric constant material. Step 110 can be or include thermal curing—i.e., the substrate may not be exposed to a plasma during the thermal curing. During step 110, an oxidant and/or an inert gas can be provided and/or a hydrogen and helium gas can be provided. The oxidant can be selected from, for example, one or more of CO, O₂, O₃, isopropyl alcohol, H₂O, or other oxidant noted herein, in any combination. A temperature of the substrate during the step of the thermal curing can be less than 500° C. In some cases, as described in more detail below, step 110 can include two or more steps.

As illustrated, method 100 can also include treatment step 112. During step 112, the cured low dielectric constant material is treated to form treated low dielectric constant material.

During step 112, one or more of capacitively coupled plasma (CCP), microwave excitation, very high frequency (VHF) excitation, and ultraviolet (UV) excitation of/with an inert gas can be used to, for example, densify the deposited material, lower the dielectric constant of the deposited material, or the like. A temperature of the substrate during the step of performing the post-deposition treatment can be less than 500° C.

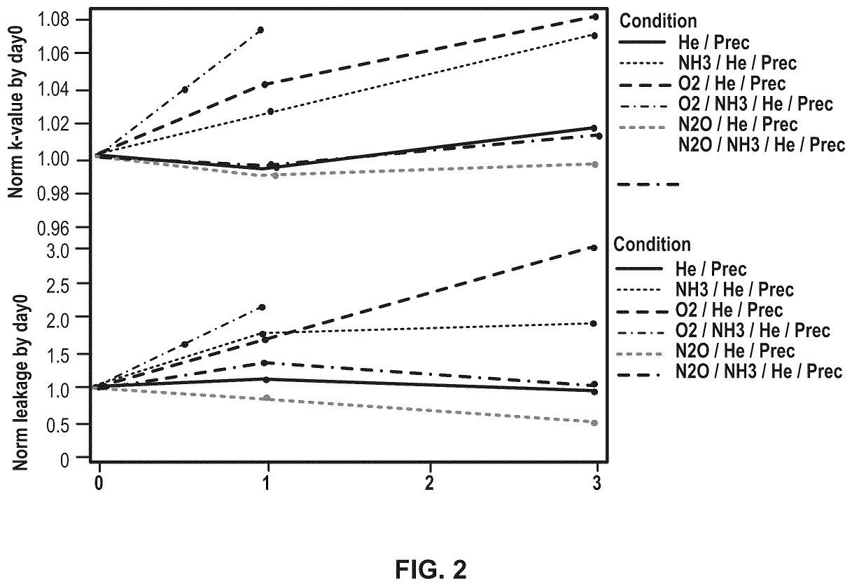

FIG. 2 illustrates normalized dielectric constant (k-value) and leakage shift over time with various combinations of reactants and oxidants used to form a low dielectric constant material. The O₂ addition as oxidant shows worst shift over time, while N₂O (a nitrogen- and oxygen-containing reactant) addition as oxidant does not show any shift overtime. In accordance with examples of the disclosure, a dielectric constant of the low dielectric constant material varies by less than two percent over three or more days in an ambient environment. In some cases, a dielectric constant leakage current of the low dielectric constant material decreases in an ambient environment over time (e.g., over three or more days).

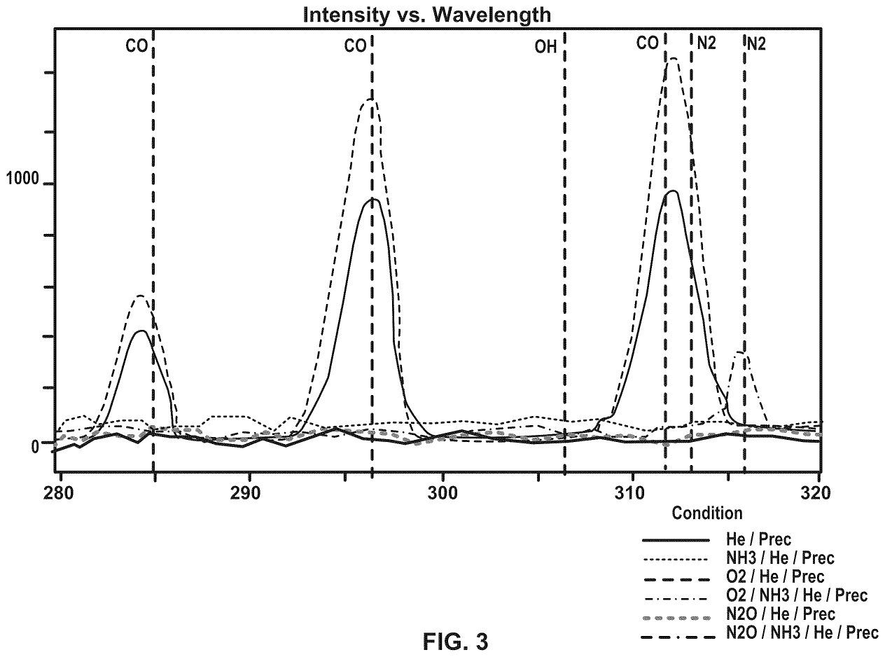

FIG. 3 illustrates the optical emission spectra at UV region from deposition plasma, measured by optical spectrometer. An OH peak is clearly detected in O₂ addition plasma, while N₂O addition plasma does not show any OH peak in the spectra. NO addition reactant and oxidant plasma (He/precursor) also does not have OH peak in the optical emission spectra from the plasma. The OH species in the plasma are thought to absorb into film as —OH termination bond or H₂O, which degrades reliability of k-value and leakage current, especially for low temperature deposition process, which cannot enhance the thermal reaction of OH to generate stable Si—O bond.

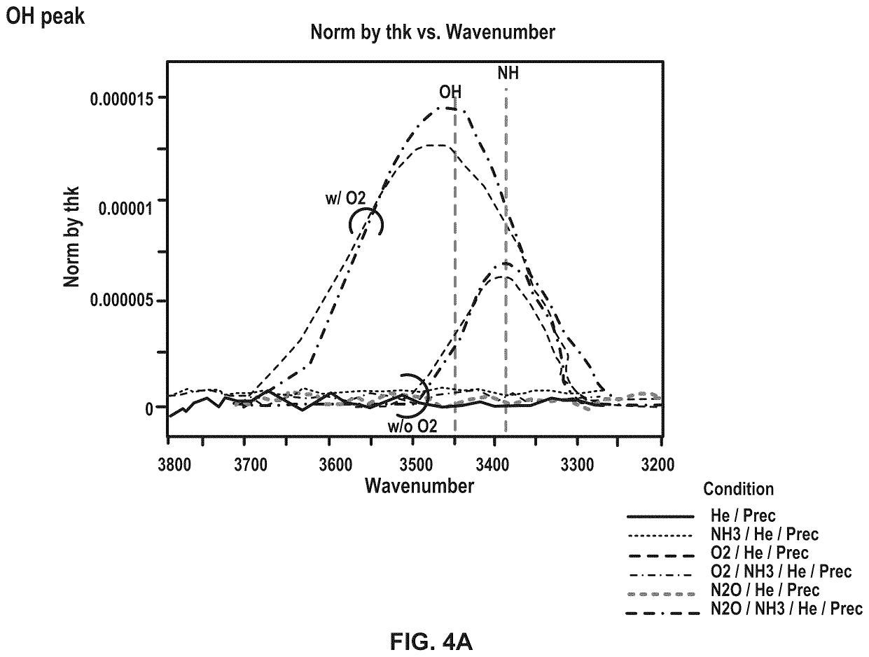

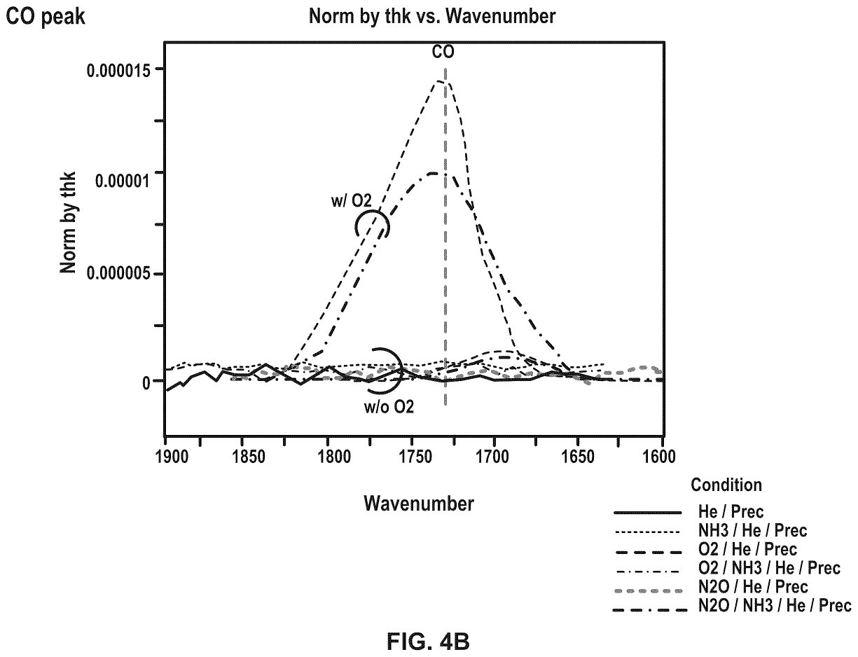

FIGS. 4A and 4B illustrate FTIR absorbance spectra normalized by thickness of film (unit: nm). The deposited film with O₂ in the plasma shows obvious OH peak at 3,450+/−20^{cm-1}, as shown in FIG. 4A. This is related to the detected OH in the optical emission of the plasma. FIG. 4B, which shows the CO region of the FTIR absorbance spectra. The deposited film with O₂ in the plasma shows obvious CO peak at 1,725+/−20^{cm-1}. These OH and CO bonding make the film hydrophilic, which increases the moisture intake to the film. The deposited film with N₂O addition plasma has less OH peak and CO peak than O₂ as oxidant.

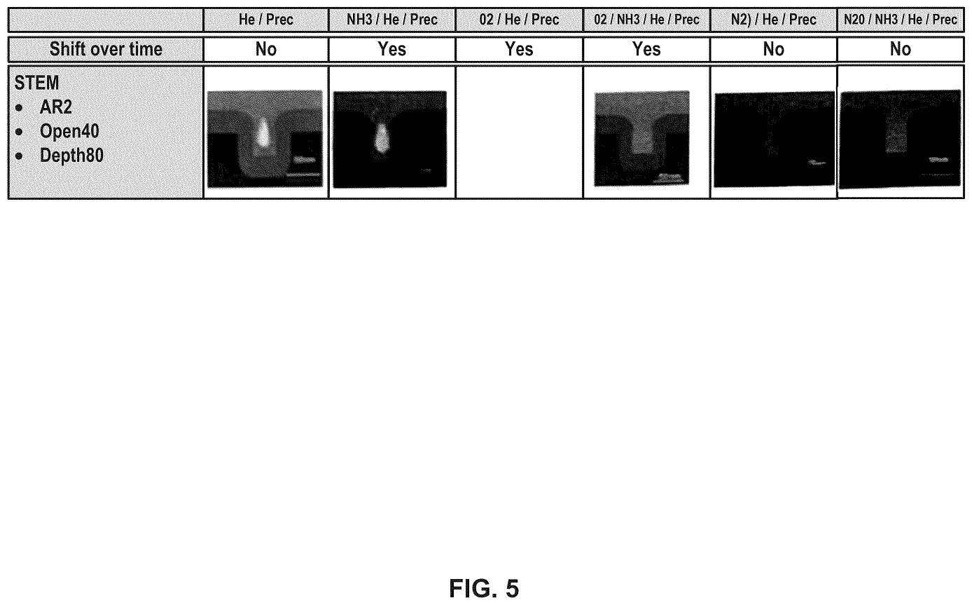

FIG. 5 illustrates gapfill performance of various process conditions. No oxidant condition has the clear void in the trench; however, with oxidant condition shows good gapfill performance.

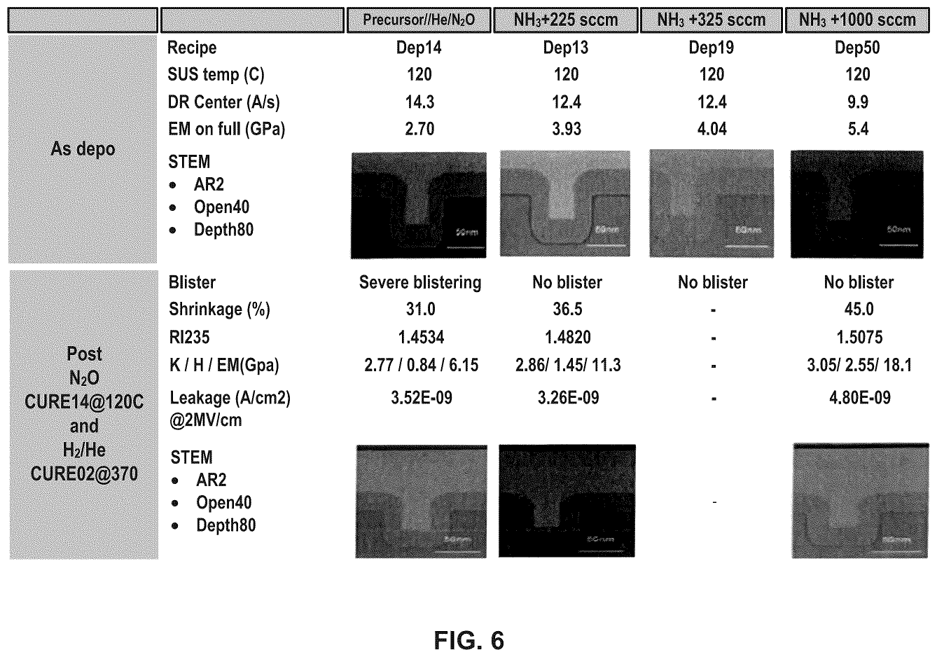

FIG. 6 illustrates examples of reduction in blistering of a low dielectric constant material during a post-deposition treatment (e.g., step 110 and/or 112). FIG. 6 illustrates a comparison between precursor+He (inert gas)+N₂O deposition and precursor+He+N₂O+NH₃ (hydrogen-containing reactant) deposition. Elastic modulus (EM) of as deposited film increased with increasing NH₃ flow. Higher EM of as deposited film suppressed blister generation in post treatment step. Highest NH₃ flow condition showed k^{˜}3 and EM 18 GPa and good gapfill without blistering.

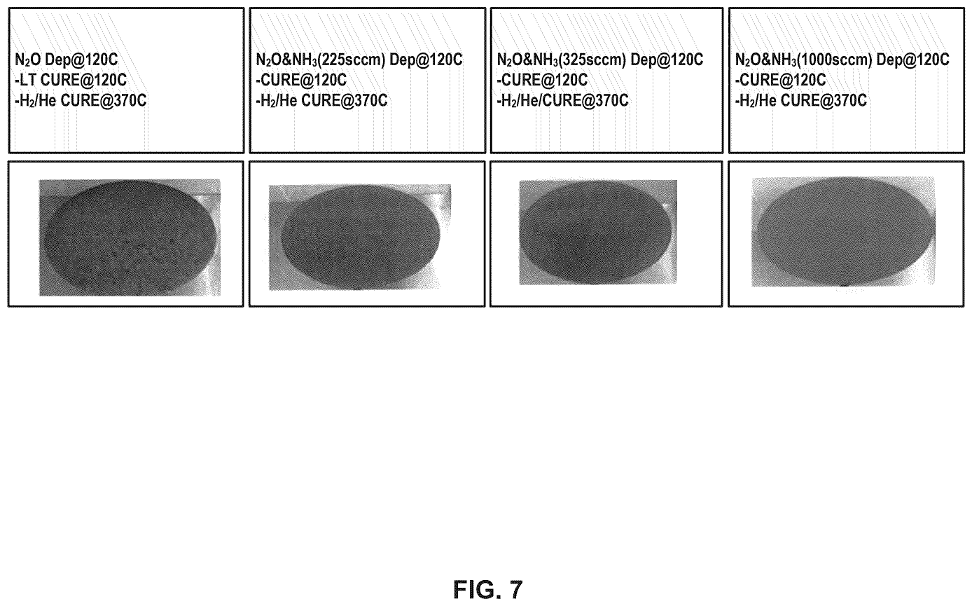

FIG. 7 illustrates silicon substrates after a 2-step treatment. As illustrated, the no NH₃ deposition sample had heavy blistering after the 2 step treatment. In the illustrated example, the two step treatment included a first low temperature (e.g., at a temperature between 50 and 200 in a N2O plasma for a duration of between about 30 and about 400 seconds) and a second cure (e.g., at a temperature between 200 and 400 in a hydrogen and helium plasma fora duration of between about 30 and about 400 seconds).

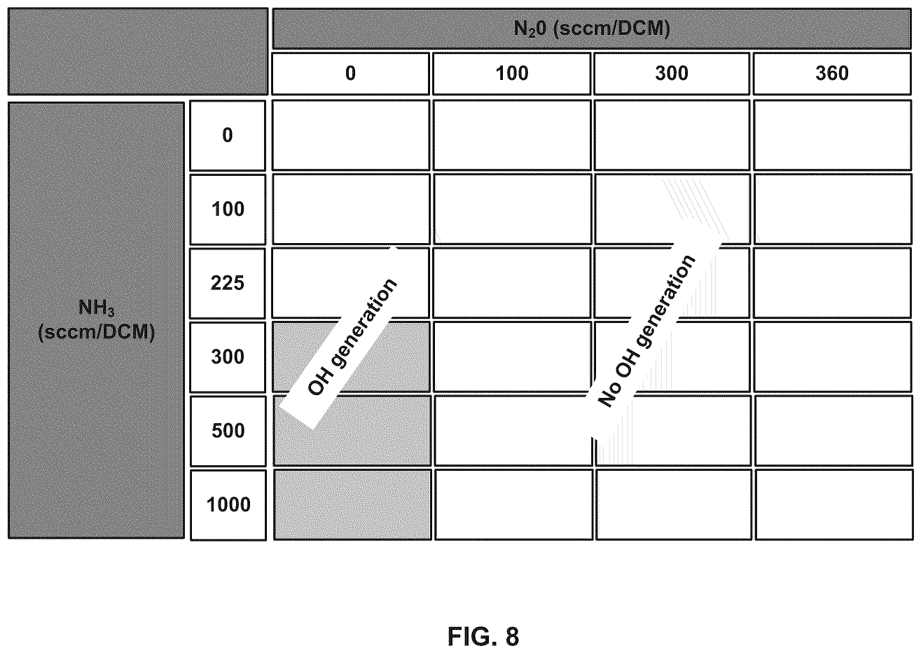

FIG. 8 illustrates OH generation in plasma with a combination of N₂O and NH₃, as measured by OES. The darker shaded regions exhibited OH generation. The lighter shaded regions did not.

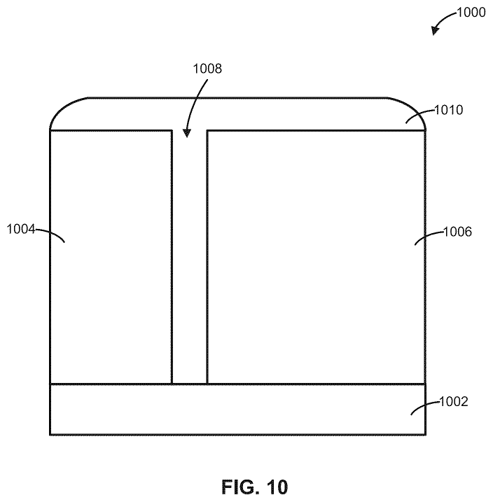

FIG. 10 illustrates a structure 1000 in accordance with further examples of the disclosure. Structure 1000 can be formed using, for example, method 100.

Structure 1000 includes a substrate 1002, one or more features 1004, 1006, a gap 1008 between features 1004, 1006, and a low dielectric constant material 1010. Structure 1000 can be used to manufacture a variety of devices and/or for a variety of applications, including a shallow trench isolation layer for FET devices, including FinFET shallow trench isolation gap fill applications, gate all around nanowire device isolation gap fill applications, cross-point devices, memory or logic devices, and the like.

Substrate 1002 can be or include any suitable substrate material, such as the substrate (bulk and/or layer) materials noted herein. In some cases, substrate 1002 can include insulating or dielectric material. In these cases, the structure can include a dielectric layer on dielectric (DOD) gap fill structure comprising dielectric material layer 1010. DOD gap fill structure can be useful in BEOL processes, particularly in logic and memory device manufacturing.

Features 1004, 1006 can be formed of a variety of materials, such as insulating, semiconducting, or conducting materials. By way of examples, features 1004, 1006 can be intermetallic features comprising one or more of Ru, Co, Cu, Ta, TaN, Ti, TiN, W, wherein low dielectric constant material layer 1010 forms an intermetallic gap-fill layer between two or more of the features 304, 306.

In accordance with examples of the disclosure, low dielectric constant material layer 1010 comprises silicon, oxygen, and carbon. Low dielectric constant material layer 1010 can include various properties of dielectric material layers noted herein.

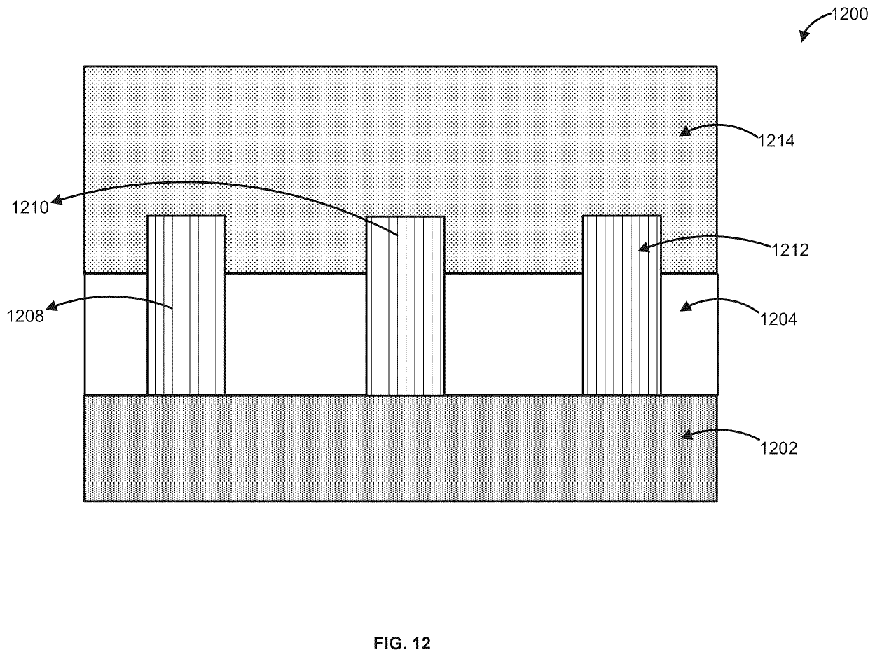

FIG. 12 illustrates a FinFET structure 1200 in accordance with additional examples of the disclosure. FinFET structure 1200 includes a substrate 1202, a fin 1204, gate features 1208-1212, and a low dielectric constant material 1214.

Substrate 1202 can include any suitable substrate materials, such as the substrate materials described herein. Fin 1204 can include one or more lateral nanowires including, for example, at least one of: silicon, germanium, silicon germanium, combinations thereof, or other semiconductor material. Gate structures 1208-1212 can include, for example, a dielectric layer and a conductive layer. Low dielectric constant material 1214 can include a low dielectric constant material formed using a method described herein.

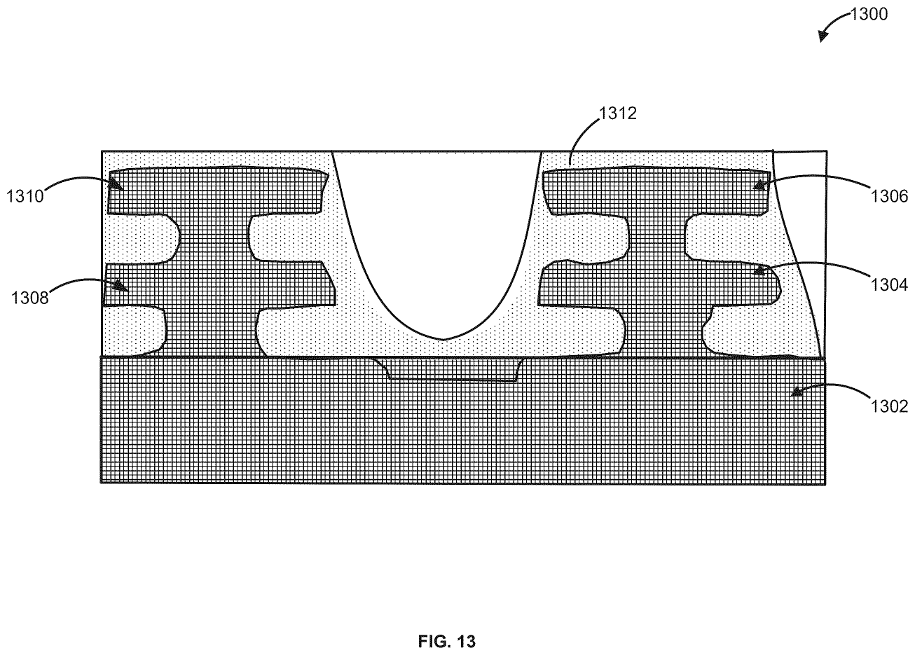

FIG. 13 illustrates a gate all around device structure 1300 in accordance with further exemplary embodiments of the disclosure. Gate all around device structure 1300 includes a substrate 1302, fins 1304-1310, and a low dielectric constant material 1312. Substrate 1302 can include any suitable substrate materials, such as the substrate materials described herein. Fins 1304-1310 can include semiconductive material, such as, for example, at least one of: silicon, germanium, silicon germanium, or combinations thereof. Gate structures can include, for example, a dielectric layer and a metal layer. Low dielectric constant material 1312 can be or include a dielectric material layer formed using a method described herein.

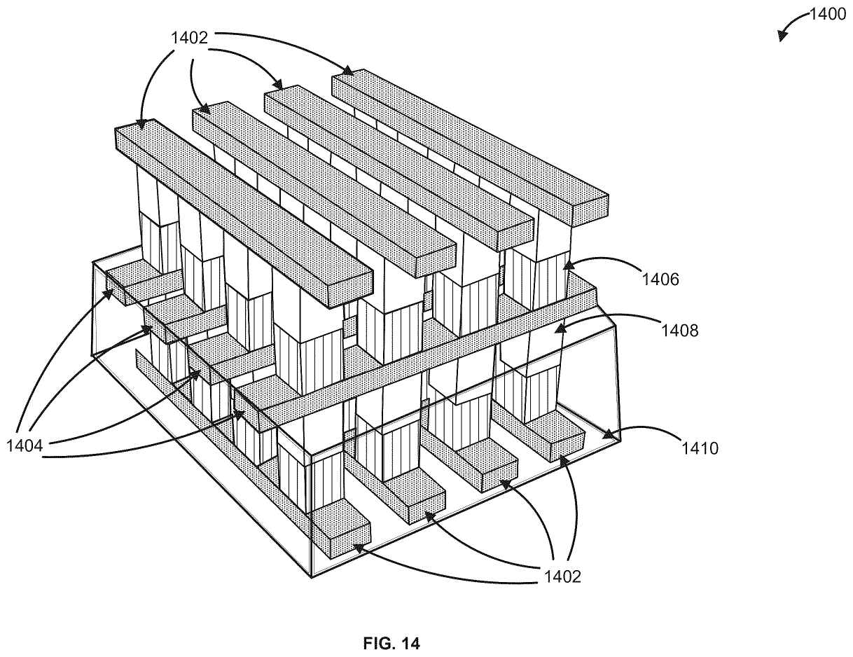

FIG. 14 illustrates a cross-point (e.g., memory) device structure 1400 in accordance with further exemplary embodiments of the disclosure. Cross-point device structure 1400 includes a plurality of bit lines 1402, a plurality of word lines 1404, a plurality of memory elements 1406, a plurality of selector devices 1408, and a low dielectric constant material 1410 surrounding at least a portion of the memory elements 1406 and/or selector devices 1412. Low dielectric constant material 1410 can include a dielectric material layer formed using a method described herein.

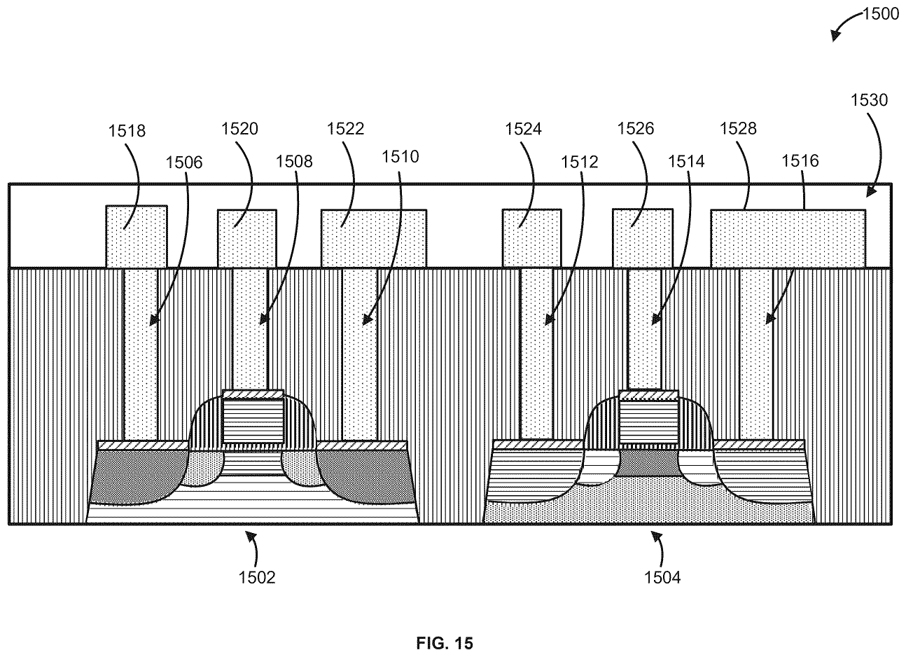

FIG. 15 illustrates a device structure 1500 in accordance with additional exemplary embodiments of the disclosure. Structure 1500 includes a first device 1502, a second device 1504, conductive plugs 1506-1516, interconnect structures 1518-1528, and a low dielectric constant material 1530 surrounding at least a portion of interconnect structures 1518-1528. Low dielectric constant material 1530 can include a dielectric material layer formed using a method described herein. FIG. 15 illustrates use of a method described herein for back-end-of-line (BEOL) intermetal dielectric (IMD) gap fill applications.

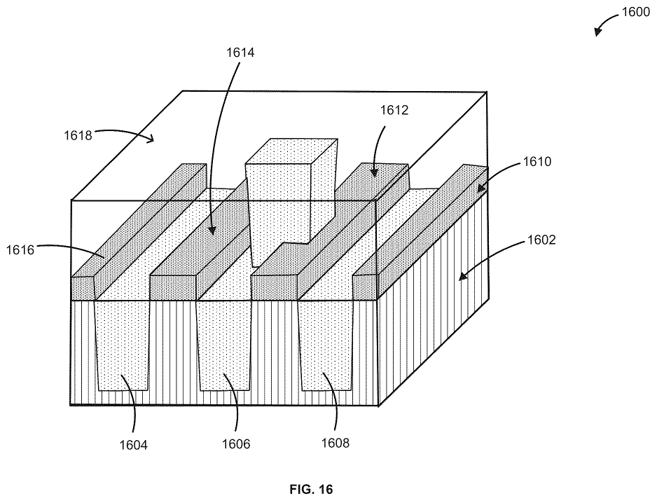

FIG. 16 illustrates a device structure 1600 in accordance with yet additional exemplary embodiments of the disclosure. Device structure 1600 include conductive features 1604-1608 formed within insulating material 1602, insulating structures 1610-1616, and a low dielectric constant material 1618 overlying conductive lines 1604-1608 and insulating structures 1610-1616. Low dielectric constant material 1618 can include a dielectric material layer formed using a method described herein. FIG. 16 illustrates use of dielectric material layer 1618 in back-end-of-line (BEOL) fully aligned via (FAV) structures.

Turning now to FIG. 11, a reactor system 1100 in accordance with exemplary embodiments of the disclosure is illustrated. Reactor system 1100 can be used to perform one or more steps or sub steps as described herein and/or to form one or more structures or portions thereof as described herein.

Reactor system 1100 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) and/or low frequency power from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 1100 can include any suitable number of gas lines.

In reaction chamber 3, a circular duct 13 with an exhaust line 7 is provided, through which gas in the interior 11 of the reaction chamber 3 can be exhausted. Additionally, a transfer chamber 5, disposed below the reaction chamber 3, is provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone is provided (a gate valve through which a wafer is transferred into or from the transfer chamber 5 is omitted from this figure). The transfer chamber is also provided with an exhaust line 6. In some embodiments, the deposition and treatment steps are performed in the same reaction space, so that two or more (e.g., all) of the steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber, and can carry the precursor gas in pulses by switching between the main line and the detour line, without substantially fluctuating pressure of the reaction chamber.

A skilled artisan will appreciate that the apparatus includes one or more controller(s) 26 programmed or otherwise configured to cause one or more method steps as described herein to be conducted. The controller(s) are communicated with the various power sources, heating systems, pumps, robotics and gas flow controllers, orvalves of the reactor, as will be appreciated by the skilled artisan.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of depositing a low dielectric constant material on a surface of a substrate, the method comprising:
providing a substrate, comprising a gap feature on a surface thereon, within a reaction chamber;
providing one or more precursors to a reaction space within the reaction chamber;
providing a reactant to the reaction space; and
providing pulsed plasma power to at least one electrode to form a plasma within the reaction space to thereby form the low dielectric constant material,
wherein the reactant comprises a mixture of 4 volumetric % or more of a nitrogen- and oxygen-containing reactant and a hydrogen-containing reactant.

2. The method of claim 1, wherein the one or more precursors comprise an alkoxy silane precursor.

3. The method of claim 2, wherein the alkoxy silane precursor is represented by the formula SiO_{z}C_{y}H_{z}, where z is between 1 and 4, y is between 3 and 10, and z is between 9 and 24.

4. The method of claim 3, wherein at least one of the one or more precursors comprises a ring structure comprising a chemical formula represented by —(Si(R₁,R₂)—O)ₙ—, where n ranges from about 3 to about 10, and wherein R₁ and R₂ are independently selected from H, CH₃, C₂H₅, C₂H₃, CH(CH₃)₂, CH₂CH(CH₃)₂, OCH₃, OC₂H₅, C₃H₆—NH₂.

5. The method of claim 3, wherein at least one of the one or more precursors comprises a linear structure comprising a chemical formula represented by R₃—(Si(R₁,R₂)ₘ—O(m−1))—R₄, where m can range from about 1 to about 7, and wherein R₁, R₂, R₃ and R₄ are independently selected from H, CH₃, C₂H₅, C₂H₃, CH(CH₃)₂, CH₂CH(CH₃)₂, OCH₃, OC₂H₅, C₃H₆—NH₂.

6. The method of claim 3, wherein the alkoxy silane precursor comprises one or more of octamethylcyclotetrasiloxane (OMCTS), tetramethylcyclotetrasiloxane (TMCTS), octamethoxydodecasiloxane (OMODDS), octamethoxycyclotetrasiloxane (OMOCTS) dimethyldimethoxysilane (DM-DMOS), diethoxymethlsilane (DEMS), dimethoxymethylsilane (DMOMS), vinylmethyldimethoxysilane (VMDMOS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), and dicyclopentyldimethoxysilane (DcPDMS).

7. The method of claim 1, wherein the hydrogen-containing reactant comprises nitrogen.

8. The method of claim 5, wherein the hydrogen-containing reactant comprises one or more of NH₃ and CₓH_{y}NH₂, where x is between 1 and 3 and y is between 3 and 7.

9. The method of claim 1, wherein the nitrogen- and oxygen-containing reactant comprises NₓO_{y}, where x is between 1 and 2 and y is between 1 and 4.

10. The method of claim 1, further comprising providing an inert gas, wherein the inert gas comprises helium or argon.

11. The method of claim 1, wherein the reactant does not comprise O₂.

12. The method of claim 1, wherein the method is a pulsed plasma-enhanced chemical vapor deposition method.

13. The method of claim 1, wherein a temperature during the step of providing pulsed plasma power to at least one electrode is less than 200° C.

14. The method of claim 1, wherein a power applied to the at least one electrode is between 10 and 2,000 W.

15. The method of claim 1, wherein a duty cycle of power applied to the at least one electrode during the step of providing pulsed plasma power to the at least one electrode is between 1% and 50%.

16. The method of claim 1, wherein a pressure within the reaction space during the step of providing pulsed plasma power to at least one electrode is between 10 and 10,000 Pa.

17. The method of claim 1, wherein the hydrogen-containing reactant comprises NH₃.

18. The method of claim 1, further comprising a step of curing the low dielectric constant material to form cured low dielectric constant material.

19. The method of claim 18, further comprising a step of treating the cured low dielectric constant material to form treated low dielectric constant material.

20. The method of claim 1, wherein a dielectric constant of the low dielectric constant material varies by less than two percent over three or more days in an ambient environment.

21. The method of claim 1, wherein a dielectric constant of the low dielectric constant material decreases in an ambient environment.

22. The method of claim 1, wherein a leakage current of the low dielectric constant material decreases in an ambient environment.
